(19) United States
(12) Patent Application Publication
(10) Pub. No.: US 2017/0086316 A1
(43) Pub. Date: Mar. 23, 2017

(54) SYSTEMS AND METHODS RELATED TO PACKAGING FOR AN ELECTRONIC DEVICE

(71) Applicant: Motorola Mobility LLC, Chicago, IL (US)

(72) Inventors: Adam C Schettle, Chicago, IL (US); Umar Hanif, Chicago, IL (US); Karl M Brower, Elmhurst, IL (US); Phillip E Hague, Chicago, IL (US); Zachary J McIntosh, Chicago, IL (US); Michael D Mizzi, Chicago, IL (US); Joey P Mullick, Chicago, IL (US); Neema Pourian, Chicago, IL (US)

(21) Appl. No.: 14/859,852

(22) Filed: Sep. 21, 2015

(51) Int. Cl. H05K 5/02; H05K 5/00; G06F 1/16

(52) U.S. Cl. CPC H05K 5/0226; G06F 1/163; H05K 5/0086

(57) ABSTRACT

Provided herein are systems and methods for packaging an electronic device.

### CROSS-REFERENCES TO RELATED APPLICATIONS

The present disclosure is related to U.S. Design application No. 29/497,928, entitled “Packaging”, filed Jul. 30, 2014 and U.S. patent application Ser. No. 14/449,171, entitled “Cylindrical Container with Side-mount Hang Tab and Methods Therefor”, filed Aug. 1, 2014, the contents of which are incorporated herein by reference in their entirety.

### FIELD

The disclosure relates generally to the field of packaging for electronic devices, and more specifically to storage and display systems for portable electronic devices.

### BACKGROUND

Packaging of electronic devices serves a number of functions including preserving or protecting the electronic devices and enticing the consumer to purchase the electronic devices. In order to accomplish these functions, a package that secures the electronic device when being handled or transported is desirable. Furthermore, a package that allows a consumer to easily view or inspect the electronic device, and in some instances try the electronic device on, before purchasing is also desirable.

The present disclosure provides systems and methods of achieving such packaging goals.

### SUMMARY

There are provided herein systems and methods for packaging that protects an electronic device during shipment from a manufacture and display at a retailer, and allows a consumer to try on or inspect the electronic device with easy removal from the packaging.

In a first aspect, a system is disclosed. The system includes: an electronic device; a base; and a tray supported by the base, the tray comprising a retention member, an alignment system and a release system, the retention member configured to support a portion of the electronic device, the alignment system comprising alignment guides configured to align the tray with the base, the release system comprising a hinge configured to release the portion of the electronic device upon transverse movement of the tray relative to the base.

In a second aspect, a method of removing an electronic device from a package is disclosed. The method includes: pulling upwardly on an electronic device located in a base assembly including a tray and housing portion, to cause the tray to lift partially out of the housing portion and causing one or more retention members on the tray to release the electronic device; and removing the electronic device from the tray.

### BRIEF DESCRIPTION OF THE DRAWINGS

The details of the present disclosure, both as to its structure and operation, may be understood in part by study of the accompanying drawings, in which like reference numerals refer to like parts. The drawings are not necessarily to scale, emphasis instead being placed upon illustrating the principles of the disclosure.

FIG. 1 shows a top perspective view of a system in accordance with an embodiment of the disclosure.

FIG. 2 shows a side view of a tray and electronic device of FIG. 1.

FIG. 3A shows a top perspective view of a retention member in accordance with an embodiment of the disclosure.

FIG. 3B shows a top perspective view of a retention member in accordance with an embodiment of the disclosure.

FIG. 3C shows a top perspective view of a retention member in accordance with an embodiment of the disclosure.

FIG. 3D shows a top perspective view of a retention member in accordance with an embodiment of the disclosure.

FIG. 3E shows a front perspective exploded view of a retention member in accordance with an embodiment of the disclosure.

FIG. 3F shows a front perspective exploded view of a retention member in accordance with an embodiment of the disclosure.

FIG. 4A shows a top perspective view of an alignment system in accordance with an embodiment of the disclosure.

FIG. 4B shows a partial front perspective view of an alignment system in accordance with an embodiment of the disclosure.

FIG. 5A shows a partial front perspective view of an alignment system in accordance with an embodiment of the disclosure.

FIG. 5B shows a top perspective view of an alignment system in accordance with an embodiment of the disclosure.

FIG. 6A shows a front cross-sectional view of a release system in accordance with an embodiment of the disclosure.

FIG. 6B shows a top perspective exploded view of a release system in accordance with an embodiment of the disclosure.

FIG. 6C shows a top perspective view of the release system of FIG. 6B.

FIG. 7A shows a front perspective view of a location for a release system and a bottom perspective view of the release system at the location in accordance with an embodiment of the disclosure.

FIG. 7B shows a front perspective view of a location for a release system and a bottom perspective view of the release system at the location in accordance with an embodiment of the disclosure.

FIG. 7C shows a front perspective view of a location for a release system and a bottom perspective view of the release system at the location in accordance with an embodiment of the disclosure.

FIG. 7D shows a front perspective view of a location for a release system and a bottom perspective view of the release system at the location in accordance with an embodiment of the disclosure.

FIG. 8A shows a bottom perspective view of a hinge in accordance with an embodiment of the disclosure.

FIG. 8B shows a bottom perspective view of a hinge in accordance with an embodiment of the disclosure.

FIG. 8C shows a bottom perspective view of a hinge in accordance with an embodiment of the disclosure.

FIG. 8D shows a bottom perspective view of a hinge in accordance with an embodiment of the disclosure.

FIG. 9A shows a top perspective view of an adhesive strip in accordance with an embodiment of the disclosure.

FIG. 9B shows a top perspective view of an insert in accordance with an embodiment of the disclosure.

FIG. 9C shows a top perspective view of snaps in accordance with an embodiment of the disclosure.

FIG. 10A shows a top perspective view of a system in a first position in accordance with an embodiment of the disclosure.

FIG. 10B shows a top perspective view of a system in a second position in accordance with an embodiment of the disclosure.

FIG. 10C shows a top perspective view of a system in a third position in accordance with an embodiment of the disclosure.

FIG. 10D shows a top perspective view of a system in a fourth position in accordance with an embodiment of the disclosure.

FIG. 11A shows a side perspective view of a system in a first position in accordance with an embodiment of the disclosure.

FIG. 11B shows a side perspective view of a system in a second position in accordance with an embodiment of the disclosure.

FIG. 11C shows a side perspective view of a system in a third position in accordance with an embodiment of the disclosure.

FIG. 11D shows a side perspective view of a system in a fourth position in accordance with an embodiment of the disclosure.

### DETAILED DESCRIPTION

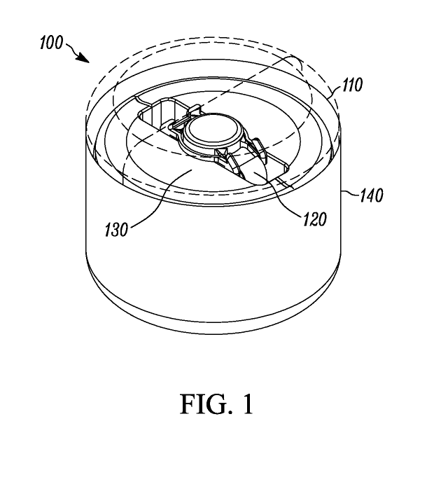

FIG. 1 shows a system for packaging and displaying an electronic device, wherein the system is designated generally by the reference numeral 100. System 100 includes a lid 110, an electronic device 120, a tray 130 and a base package 140. As shown, lid 110 covers electronic device 120 by engaging the tray 130 or base package 140.

In some embodiments, lid 110 is constructed from a transparent or translucent material such as acrylonitrile butadiene styrene (ABS), polymethyl methacrylate (acrylic), styrene/methyl methacrylate copolymer (SMMA), nylon, polycarbonate (PCB), polystyrene (PS), or polyetherimide (PEI). In some embodiments, the optical transmission for such transparent or translucent material is approximately 90-100%. As shown, lid 110 has a flat surface comprising the top and one or more sides that engage the tray 130 and/or base package 140. The one or more sides of lid 110 may provide a gap area above electronic device. Suitable dimensions for lid 110 include, for example, 133 mm diameter, 3 mm thickness, 29 mm height. It should be appreciated that these dimensions are exemplary only, and that any suitable dimensions for packaging an electronic device may be used.

As shown, electronic device 120 is a wristwatch or smartwatch. However, electronic device 120 may be any type of portable electronic device including: a global positioning system (GPS), personal computer (PC) or personal computing device, a tablet such as an iPad, a personal gaming device such as a Nintendo DS, mobile telephones, smartphones, Bluetooth headsets, cameras, or any other type of personal electronics such as an iPod.

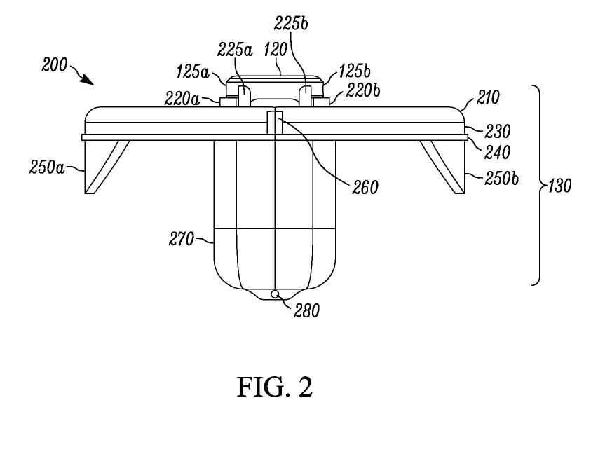

In some embodiments, tray 130 is constructed from a pliable material such as acrylonitrile butadiene styrene (ABS), polymethyl methacrylate (acrylic), styrene/methyl methacrylate copolymer (SMMA), nylon, polycarbonate (PCB), polystyrene (PS), polyetherimide (PEI), or polypropylene (PP). Tray 130 has a flat plane portion, on which electronic device 120 is mounted or supported. Tray 130 includes a retention member, an alignment system and a release system. These items are further discussed in reference to FIGS. 2-6. Suitable dimensions for tray 130 include, for example, 129 mm length, 65 mm width, 68.2 mm height, and 2 mm wall thickness. It should be appreciated that these dimensions are exemplary only, and that any suitable dimensions for packaging an electronic device may be used.

In some embodiments, base package 140 is constructed from a rigid or semi-rigid material such as a polymer (e.g. ABS or polycarbonate) or a wood or paper-based material (e.g., cardboard tubing). As shown, base package 140 has a flat surface comprising the bottom and one or more sides that engage the tray 130 and/or lid 110. The one or more sides of base package 140 provide a housing for receiving the tray 130. Suitable dimensions for base package 140 include, for example, 130 mm inside diameter. The thickness can vary based on material and the height varies based on the included electronic device and its accessories.

FIG. 2 shows a front cross-sectional view of a tray and electronic device of FIG. 1. The tray 130 and electronic device 120 are referred to generally by reference numeral 200. Electronic device 120 includes one or more engagement portions 125a, 125b that may be engaged or supported by tray 130.

Tray 130 includes a flat plane portion 210 and an elongated cavity 270. In some embodiments, flat plane portion 210 includes one or more retention members located on top of the flat plane portion 210. As shown, the retention members may include a retention member or finger 225a, 225b and a support member 220a, 220b. In such embodiments, the retention member or finger 225a, 225b engages the electronic device 120 via engagement portions 125a, 125b, such as by covering a portion of engagement portions 125a, 125b to hold it in place. Support member 220a, 220b may also cover a portion of electronic device 120, or may alternately provide mechanical support to retention members or fingers 225a, 225b.

Flat plane portion 210 may also include rounded corner 230, a tray ridge or lip 240, and one or more alignment guides 250a, 250b. In some embodiments, tray lip 240 allows the tray 130 to rest on a ledge or surface of base package 130, without wedging or falling into base package 130. In some embodiments, the alignment guides 250a, 250b are fins that allow the tray 130 to slide into the base package 130 after the device 120 is removed from the tray 130, as described in further detail below. Flat plane portion 210 may also include an alignment feature such as a recess 260, which allows the tray 130 to line up properly with other system components, such as lid 110 and/or base package 140. As used herein, items that aid in aligning the tray 130 within system 100 may be collectively referred to as an “alignment system”.

Elongated cavity 270 includes a coupling mechanism such as a hinge 280. Hinge 280 allows the elongated cavity 270 to open or blossom, which allows the electronic device 120 to be released from tray 130.

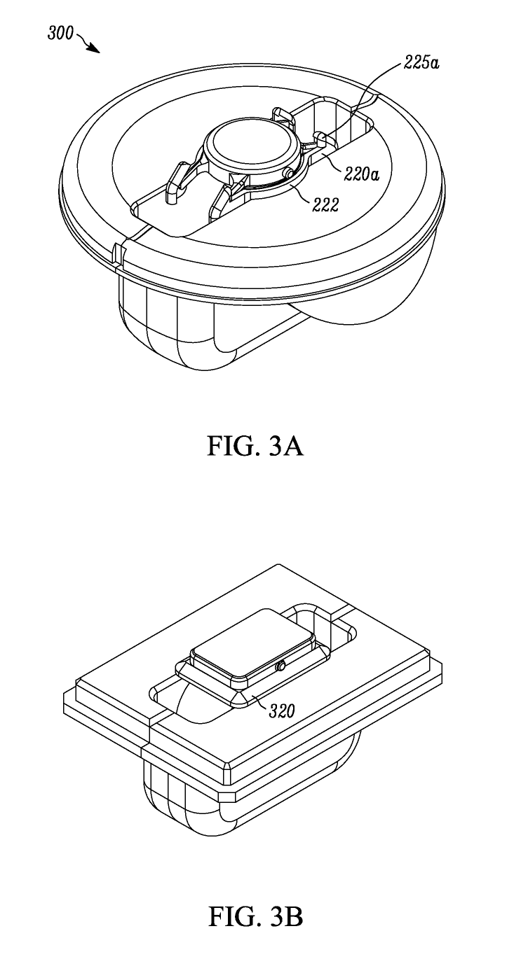

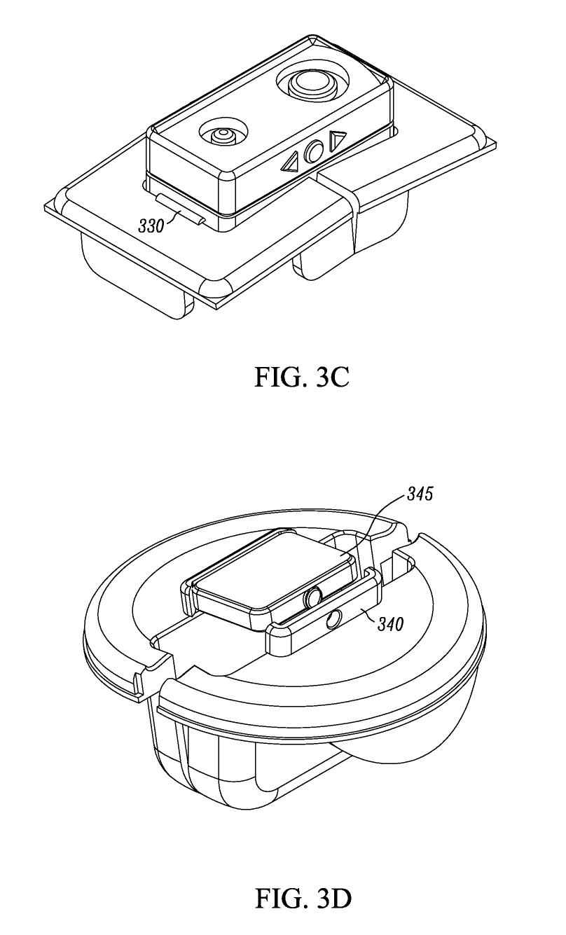

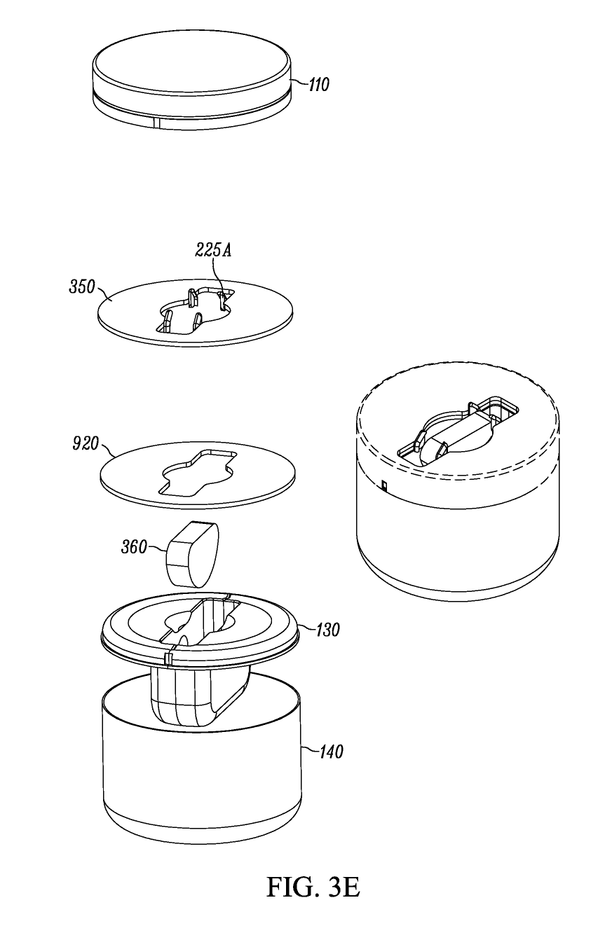

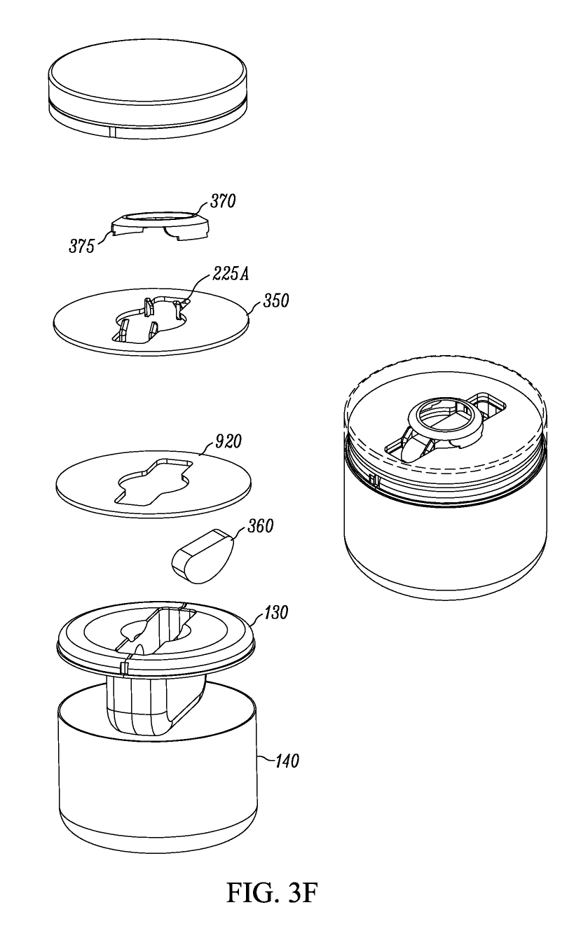

FIG. 3A shows a top perspective view of a retention member in accordance with an embodiment of the disclosure. The retention member 300 may include a plurality of connected regions or separate pieces. As shown, retention member 300 includes a retention member or finger 225a, a support member 220a and a bridge member 222. Similar to FIG. 2, retention finger 225a is integral to and extends from the flat plane portion 210 to cover a portion of the electronic device (designated as engagement portions 125a in FIG. 2). By only engaging a portion of the electronic device 120 at engagement portions 125a, the retention member 300 allows a user or customer to see most of electronic device 120 when secured in tray 130. Support member 220b may provide structural support to finger 225a and/or engagement portions 125a. Bridge member 222 extends from a first support member 220a to a second support member (not shown), thus bridging two retention members. In some embodiments, bridge member 222 provides a resting area or supports electronic device 120 while it is in tray 120.

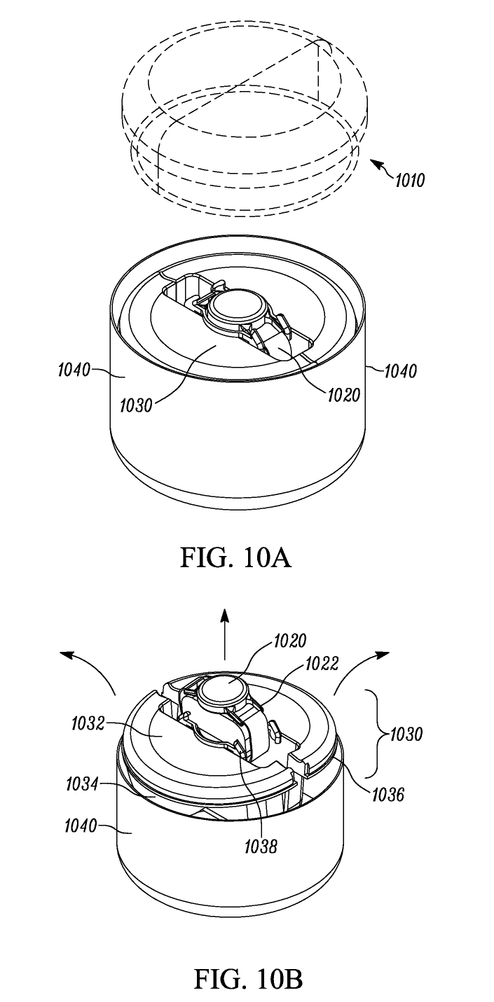

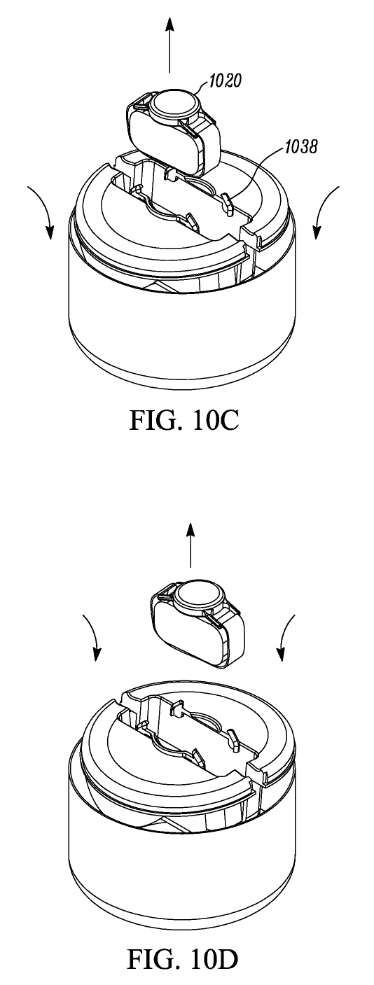

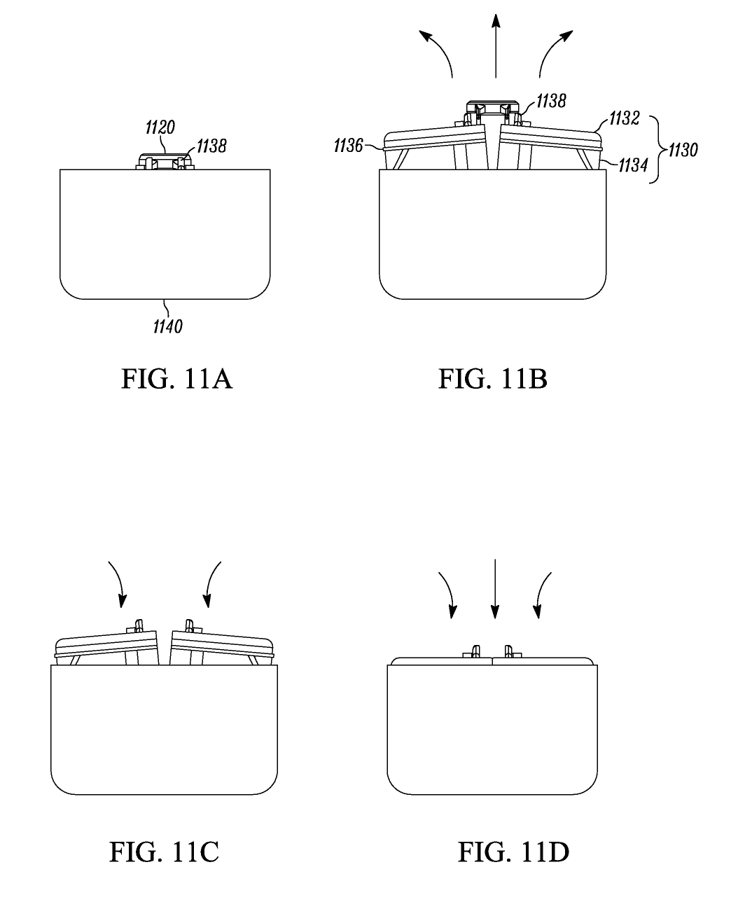

In operation, as the user/operator pulls the electronic device 120 to remove it from the package 100, the electronic device 120 pushes against the fingers 225a causing the tray assembly 130 to open. Once open, the electronic device 120 can be removed and the tray 130 will return to its resting position. This is discussed in further detail below with FIG. 10 and FIG. 11.

FIG. 3B shows a top perspective view of a retention member in accordance with an embodiment of the disclosure. In FIG. 3B, an over the side or strap retention member 320 is shown. Strap retention member 320 retains the electronic device over the top of a protruding feature, such as a bendable wristband. In some embodiments, strap retention member 320 includes two mating halves that surround the electronic device and break apart similar to elongated cavity 270. While shown as relatively square or rectangular, strap retention member 320 may be any suitable shape, including circular or cupped.

FIG. 3C shows a top perspective view of a retention member in accordance with an embodiment of the disclosure. In FIG. 3C, an into product retention member 330 is shown. Into product retention member 330 engages the electronic device by pinching or penetrating features, such as notches or grooves (not shown), in the electronic device.

FIG. 3D shows a top perspective view of a retention member in accordance with an embodiment of the disclosure. In FIG. 3D, an over the top retention member 340 is shown. Over the top retention member 340 engages electronic device by at least partially reaching over or covering a part of the electronic device. As shown, over the top retention member 340 engages a rim or edge 345 of the electronic device.

FIG. 3E shows a front perspective exploded view of a retention member in accordance with an embodiment of the disclosure. The retention member is a retainer plate 350 with a plurality of retention fingers 225a. The retainer plate 350 is parallel to and rests between tray 130 and lid 110. In some embodiments, retainer plate 350 is configured to engage lid 110, such as via sonic welding, snap fit features, adhesives, etc.

Also shown in FIG. 3E, are a paper insert 920 and an electronic device package insert 360 between retainer plate 350 and tray 130. Electronic device package insert 360 provides a resting and/or securement piece for electronic device 120, as is well known in the art.

FIG. 3F shows a front perspective exploded view of a retention member in accordance with an embodiment of the disclosure. The retention member is a retention ring 370. In some embodiments, retention ring 370 includes a plurality of ring members 375 that are configured to engage tray 130, locking retention ring 370 into place. As shown, retention ring 370 engages with retainer plate 350 to aid in securing electronic device. However, in other embodiments, retention ring 370 engages directly with tray 130.

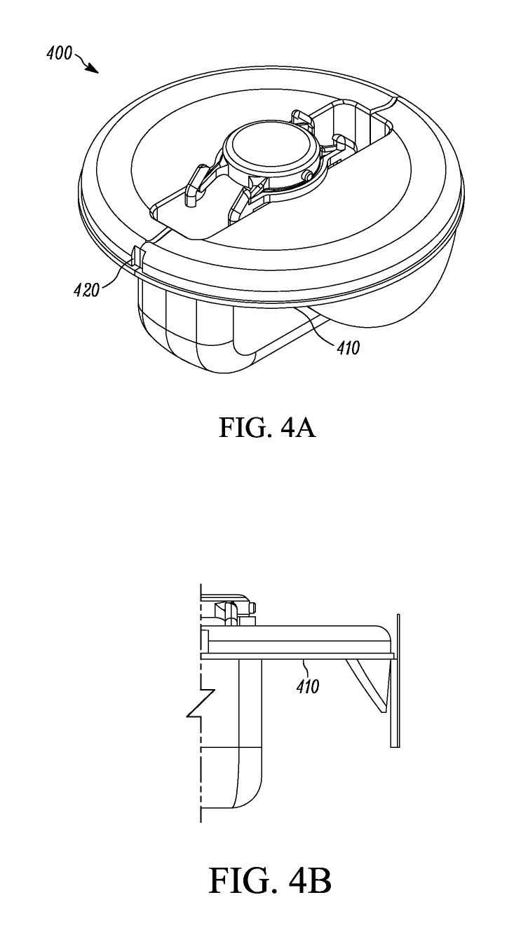

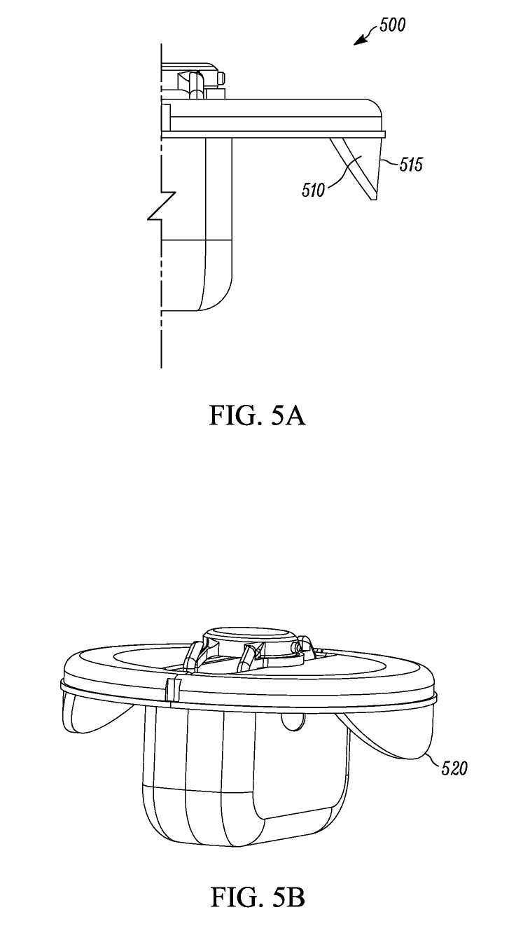

FIG. 4A shows a top perspective view of an alignment system in accordance with an embodiment of the disclosure. Alignment system 400 includes a lip 410, a notch or recess 420, and alignment guides 510 (see FIG. 5A). Lip 410 extends around a bottom edge of tray 130, allowing it to rest on an edge of the base package 140, such as shown in FIG. 4B. Lip 410 may also prevent tray 130 from wedging into base package 140 upon reentry, as described in the discussion of FIG. 10 and FIG. 11. Notch or recess 420 may be formed within a portion of the tray 130, such as where the tray 130 may be separated during electronic device 120 removal. In some embodiments, there are two or more notch or recesses 420 within tray 130. Such notch or recess 420 allows the tray 130 to correctly align with the lid 110, such as by receiving a protrusion from the lid 110. In some embodiments, notch or recess 420 is configured to receive a protrusion from base package 140 to align the tray 130 with base package 140.

FIG. 5A shows a partial front perspective view of an alignment system in accordance with an embodiment of the disclosure. Alignment system 500 includes alignment guides 510, shown here as fins. In some embodiments, the fins have a curved geometry as depicted by reference numeral 515. The curved fin geometry 515 allows the fins to slide into and out of the base package 140 without wedging or becoming stuck. In some embodiments, the fins may include a chamfered edge 520 to help guide the fins back into place, such as shown in FIG. 5B.

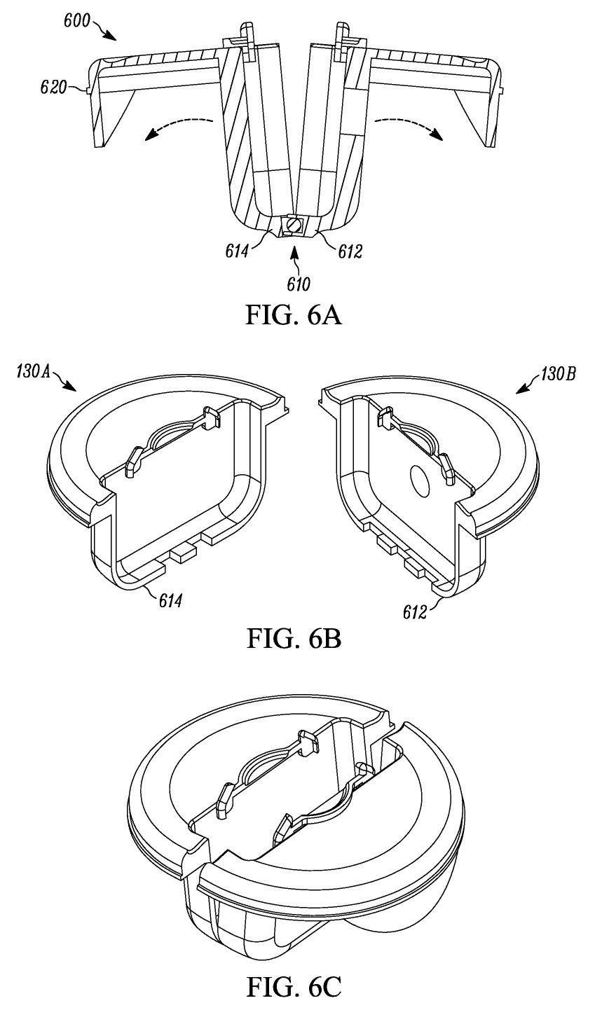

FIG. 6A shows a front cross-sectional view of a release system in accordance with an embodiment of the disclosure. Release system 600 includes a hinge 610 connecting a first cavity portion 612 and a second cavity portion 614 of the elongated cavity 270. In some embodiments, hinge 610 is configured to release the electronic device 120 from tray 130 upon transverse movement of the tray 130 relative to the base package 140. As shown in FIG. 6A, the hinge 610 is located at the bottom of the elongated cavity 270, farthest from the retention members 300. Placement of hinge 610 at the bottom of cavity 270 may allow for a small opening angle (e.g., 10°) for a user to retrieve the electronic device 120. Also shown in release system 600 is lip 620 (similar to lip 410 in FIG. 4). As shown, lip 620, prevents hinge 610 from opening until the hinge 610 is moved vertically. Additionally, lip 620 helps guide tray 130 back into play upon reentry into the base package.

FIG. 6B shows a top perspective exploded view of a release system in accordance with an embodiment of the disclosure. The release system shows first cavity portion 612 and second cavity portion 614 of the elongated cavity 270 separated from each other. FIG. 6C shows a top perspective view of the release system of FIG. 6B, with first cavity portion 612 and second cavity portion 614 connected. As can be appreciated, the first cavity portion 612 and second cavity portion 614 correlate to a first portion 130a and second portion 130b of tray 130, respectively.

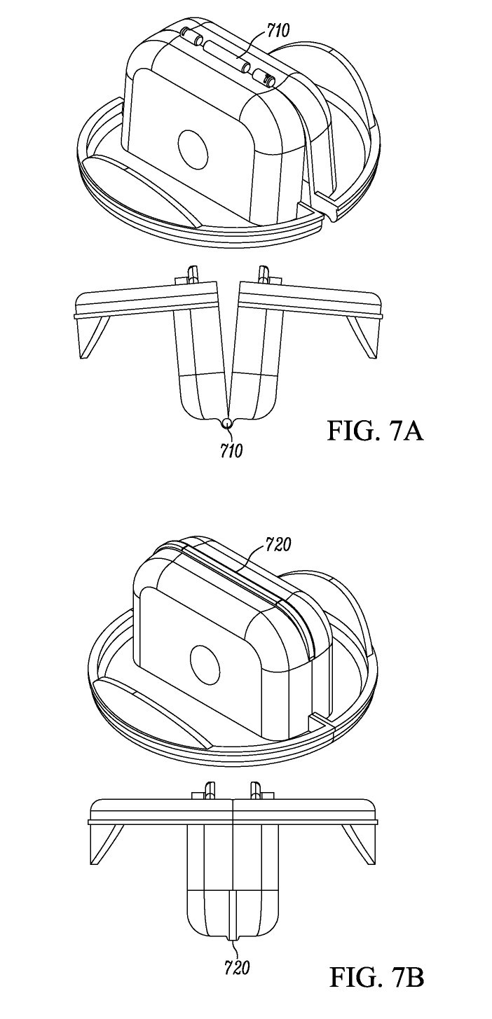

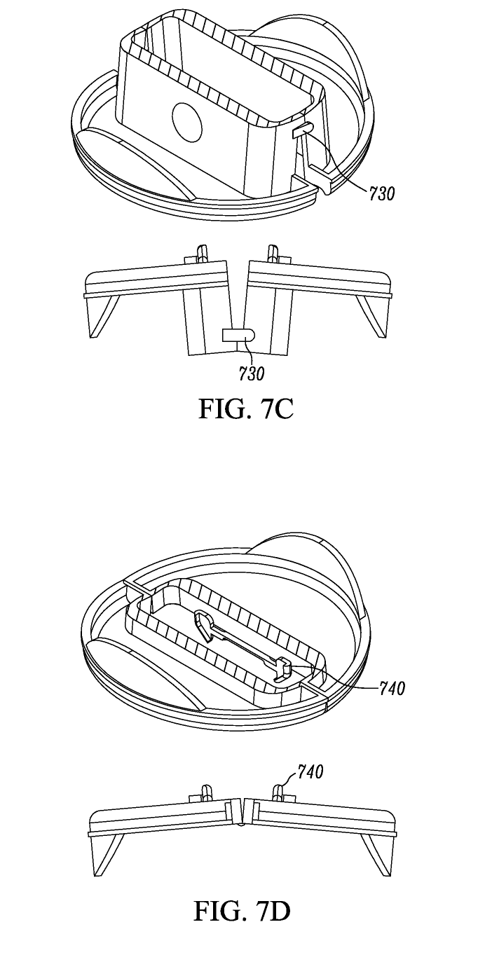

FIG. 7A shows a front perspective view of a location for a release system and a bottom perspective view of the release system at the location in accordance with an embodiment of the disclosure. As shown, a hinge is located at the underside 710 of tray 130 such that the hinge protrudes out.

FIG. 7B shows a front perspective view of a location for a release system and a bottom perspective view of the release system at the location in accordance with an embodiment of the disclosure. As shown, a hinge is integrated 720 within tray 130. The hinge may be integrated 720 such that the hinge is between the first cavity portion 612 and second cavity portion 614 or within the wall of a cavity portion 612, 614.

FIG. 7C shows a front perspective view of a location for a release system and a bottom perspective view of the release system at the location in accordance with an embodiment of the disclosure. As shown, a hinge is located on the side of tray 130.

FIG. 7D shows a front perspective view of a location for a release system and a bottom perspective view of the release system at the location in accordance with an embodiment of the disclosure. As shown, a hinge is located high (e.g., near or at the top of tray 130 where the retention members 300 are located).

FIGS. 6A, 6B, 7A, 7B, 7C and 7D have shown a single hinge 610 for use in the release system 600. Each one of the hinges 610 preferably prevents the first cavity portion 612 and second cavity portion from opening too much, such as by including a stop feature, as is known in the art. The present disclosure contemplates the use of two or more hinges 610 as well. For example, another hinge may be added that is in a perpendicular plane to existing hinge 610, causing tray 130 to split into four portions to release electronic device 120.

While a variety of hinge locations have been provided in FIGS. 7A, 7B, 7C and 7D, a variety of hinge types may be used. For example, suitable hinges include taped hinges, living hinges, hook hinges, side hinges, integrated hinges, peg hinges, among others.

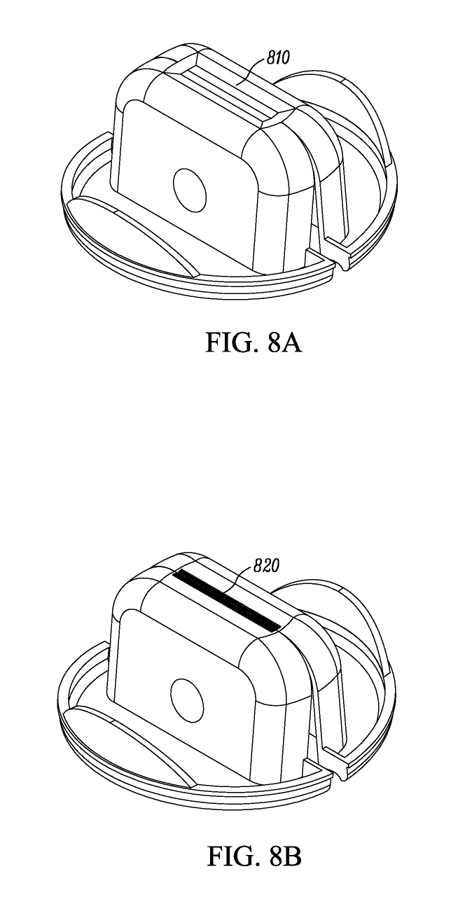

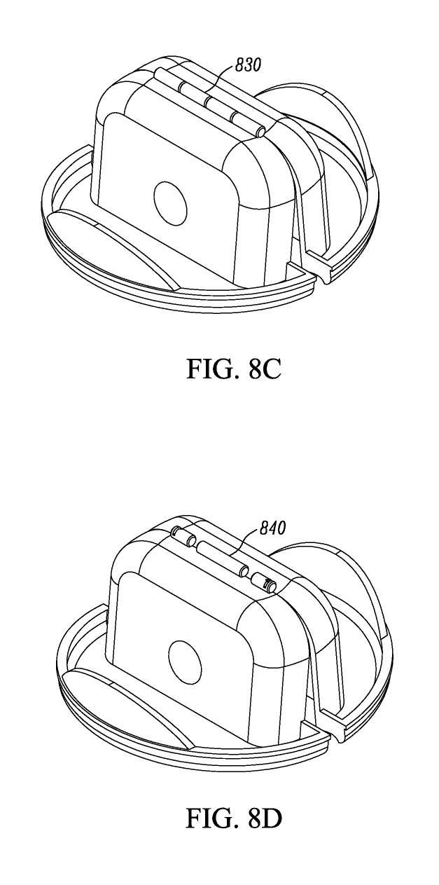

FIG. 8A shows a bottom perspective view of a hinge in accordance with an embodiment of the disclosure. Hinge 810 is a taped hinge or connection that allows the cavity portions to hinge.

FIG. 8B shows a bottom perspective view of a hinge in accordance with an embodiment of the disclosure. Hinge 820 is a living hinge or connection that allows the cavity portions to hinge.

FIG. 8C shows a bottom perspective view of a hinge in accordance with an embodiment of the disclosure. Hinge 830 is a hook hinge that hooks both cavity portions together loosely.

FIG. 8D shows a bottom perspective view of a hinge in accordance with an embodiment of the disclosure. Hinge 840 is a peg hinge, where pegs snap into a barrel cavity to rotate.

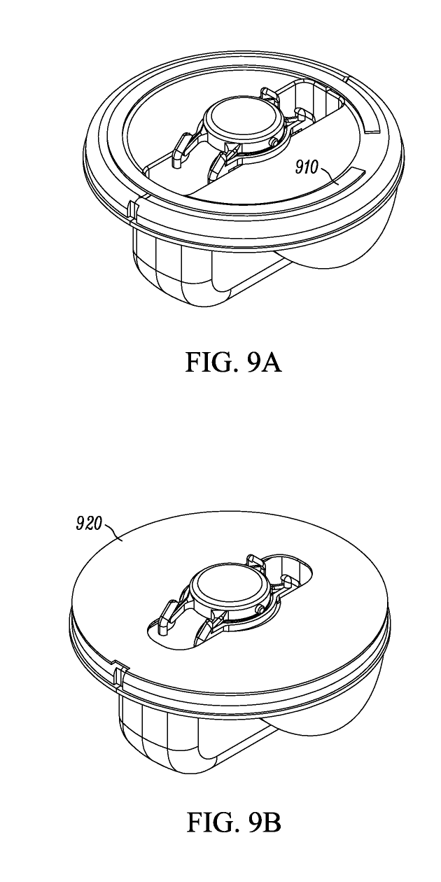

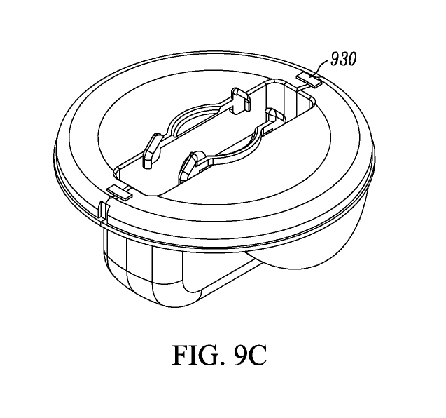

FIG. 9A shows a top perspective view of a security seal in accordance with an embodiment of the disclosure. Security seal 910 may include tape or adhesive strip attached to tray 130. In some embodiments, security seal 910 keeps tray 130 from opening or separating, thereby preventing electronic 120 from being released.

FIG. 9B shows a top perspective view of an insert in accordance with an embodiment of the disclosure. Insert 920 may be a paper insert that prevents tray 130 from opening or separating. Alternatively, insert 920 may be made from any rigid material such as plastic, paper pulp or wood.

FIG. 9C shows a top perspective view of snaps in accordance with an embodiment of the disclosure. Snaps 930 may operate to snap first portion 130a of tray 130 to second portion 130b of tray 130. Snaps 930 may be on top of or integral to tray 130.

FIG. 10A shows a top perspective view of a system in a first position in accordance with an embodiment of the disclosure. System 1000 includes a lid 1010, an electronic device 1020, a tray 1030, and a base package 1040. Also shown are retention members 1038, which engage or retain electronic device 1020 when in a resting or first position. The tray 1030 is configured to secure the electronic device 1020 without visually blocking it for a user or consumer.

FIG. 10B shows a top perspective view of a system in a second position in accordance with an embodiment of the disclosure. In FIG. 10B, electronic device 1020 includes one or more engagement portions 1020 that may be engaged or supported by retention members 1038 of tray 1030. Tray 1030 also includes flat plane portion 1032, lip 1036 and fins 1034. As indicated by the upward arrows, the electronic device 1020 is being pulled out of the tray 1030. As the device 1020 moves upward, the hinged tray 1030 blossoms or opens, releasing the electronic device. In some embodiments, hinged tray 1030 moves upward or transverse to the base package 1040 along with the device 1020.

FIG. 10C shows a top perspective view of a system in a third position in accordance with an embodiment of the disclosure. Once the electronic device is fully released from or clears the tray 1030, the tray begins to fall or slide back down (as indicated by the downward arrows) into base package 1040.

FIG. 10D shows a top perspective view of a system in a fourth position in accordance with an embodiment of the disclosure. In some embodiments, upon removing the electronic device 1020, the hinge from hinged tray 1030 causes the two portions of tray 1030 to matingly engage, which causes tray 1030 to fall back into base package 1040. The fins 1034 or alignment guides are configured to guide tray 1030 neatly back into base package 1040.

FIG. 11A shows a side perspective view of a system in a first position in accordance with an embodiment of the disclosure. System 1100 includes an electronic device 1120, a tray 1130 including retention members 1038, and a base package 1140. Similar to FIG. 10A, the system 1100 is in a resting or first position. The tray 1130 is configured to secure the electronic device 1120 without visually blocking it for a user or consumer.

FIG. 11B shows a side perspective view of a system in a second position in accordance with an embodiment of the disclosure. Tray 1130 also includes flat plane portion 1132, lip 1136 and fins 1134. As indicated by the upward arrows, the electronic device 1120 is being pulled out of the tray 1130. As the device 1120 moves upward, the hinged tray 1130 blossoms or opens, releasing the electronic device.

FIG. 11C shows a side perspective view of a system in a third position in accordance with an embodiment of the disclosure. In FIG. 11C, the electronic device 1120 has been completely removed. The arrows indicate that the tray 1130 begins to slide back down into base package 1140.

FIG. 11D shows a side perspective view of a system in a fourth position in accordance with an embodiment of the disclosure. At the final position, the tray 1130 is shown completely back in base package 1140. The fins 1134 are configured to allow the tray 1130 to slide neatly back into base package 1140.

Although described specifically throughout the entirety of the instant disclosure, representative embodiments have utility over a wide range of applications, and the above discussion is not intended and should not be construed to be limiting, but is offered as an illustrative discussion of aspects of the disclosure. What has been described and illustrated herein are embodiments of the disclosure along with some of their variations. The terms, descriptions and figures used herein are set forth by way of illustration only and are not meant as limitations. Those skilled in the art will recognize that many variations are possible within the spirit and scope of the disclosure, wherein the disclosure is intended to be defined by the following claims—and their equivalents—in which all terms are mean in their broadest reasonable sense unless otherwise indicated.

What is claimed is:

1. A system comprising:
an electronic device;
a base; and
a tray supported by the base, the tray comprising a retention member, an alignment system and a release system, the retention member configured to support a portion of the electronic device, the alignment system comprising alignment guides configured to align the tray with the base, the release system comprising a hinge configured to release the portion of the electronic device upon transverse movement of the tray relative to the base.

2. The system of claim 1, wherein the tray further comprises a flat plane portion having the retention member located on top of the flat plane portion, wherein the flat plane portion is substantially parallel with a portion of the base.

3. The system of claim 2, wherein the retention member comprises one or more retention fingers that is integral to and extends from the flat plane portion to cover a portion of the electronic device.

4. The system of claim 2, wherein the retention member comprises one or more retention tabs that is integral to and extends from the flat plane portion to reach into a recess in the electronic device.

5. The system of claim 2, wherein the retention member comprises a retention ring proximate to the flat plane portion of the tray, the retention ring covering a portion of the electronic device.

6. The system of claim 5, wherein the retention ring comprises retention tabs, wherein the flat plane portion of the tray comprises recesses for receiving said retention tabs, and wherein when the retention tabs are received into said recesses, the retention ring is locked into place.

7. The system of claim 2, wherein the retention member comprises a retention plate proximate to the flat plane portion of the tray, the retention plate comprising one or more retention fingers that is integral to and extends from the retention plate to cover a portion of the electronic device.

8. The system of claim 1, wherein the alignment guides comprise one or more fins extending from the tray and received into the base.

9. The system of claim 8, wherein the fins comprise a curved shape to facilitate entry into the base.

10. The system of claim 1, wherein the alignment system further comprises a lip located on an edge of the tray, the lip configured to allow the tray to rest on a surface of the base.

11. The system of claim 1, wherein the transverse movement of the tray relative to the base comprises the electronic device being pulled upwardly to remove it from the system.

12. The system of claim 1, wherein the tray further comprises an elongated cavity, the elongated cavity including a first cavity portion and a second cavity portion, the first cavity portion connected to the second cavity portion via the hinge.

13. The system of claim 12, wherein the hinge is located at an end of the elongated cavity.

14. The system of claim 12, wherein the hinge is located along the elongated cavity in between a first end and a second end of the elongated cavity.

15. The system of claim 12, wherein the hinge is selected from the group consisting of: taped hinges, living hinges, hook hinges, side hinges, integrated hinges and peg hinges.

16. The system of claim 16, wherein the hinge is a living hinge and wherein the first cavity portion and second cavity portion comprise a one piece elongated tray having the living hinge integral to the one piece elongated tray.

17. A method of removing an electronic device from a package, the method comprising:
pulling upwardly on an electronic device located in a base assembly including a tray and housing portion, to cause the tray to lift partially out of the housing portion and causing one or more retention members on the tray to release the electronic device; and
removing the electronic device from the tray.

18. The method of claim 17, wherein the tray further comprises a first cavity portion, a second cavity portion, and a hinge disposed between the first cavity portion and second cavity portion and wherein upon the electronic device being pulled upwardly, the hinge allows the first cavity portion and second cavity portion to separate from each other to release the electronic device.

19. The method of claim 18, wherein upon the first cavity portion and second cavity portion separating from each other, the tray is partially pulled out of the housing portion and the retention member is disengaged from the electronic device, thereby releasing the electronic device.

20. The method of claim 18, wherein upon removing the electronic device, the hinge causes the first cavity portion and second cavity portion to matingly engage, which causes the tray to fall back into the housing portion.

21. The method of claim 20, wherein the tray further comprises alignment guides configured to guide the tray into the housing portion.
